(19) United States
(12) Patent Application Publication
(10) Pub. No.: US 2026/0310259 A1
(43) Pub. Date: Oct. 8, 2026

(54) WINDOW, METHOD OF MANUFACTURING WINDOW, AND ELECTRONIC DEVICE INCLUDING WINDOW

(71) Applicant: Samsung Display Co., LTD., Yongin-si (KR)

(72) Inventors: SEUNG-WON KUK, Yongin-si (KR); Hyunseok OH, Yongin-si (KR); HYUNKYUNG YUN, Yongin-si (KR); KANG-WOO LEE, Yongin-si (KR); JOOHYEON LEE, Yongin-si (KR)

(21) Appl. No.: 19/554,764

(22) Filed: Mar. 3, 2026

(30) Foreign Application Priority Data
Apr. 4, 2025 (KR) 10-2025-0043857

(51) Int. Cl. G06F 1/16; B05D 1/26; B05D 1/28; B05D 3/10; H04M 1/02

(52) U.S. Cl. CPC G06F 1/1641; B05D 1/26; B05D 1/28; B05D 3/104; B05D 2203/35; B05D 2518/10; H04M 1/0216

(57) ABSTRACT

A window, in which a folding area, a first non-folding area adjacent to one side of the folding area, and a second non-folding area adjacent to an opposing side of the folding area are defined, includes a substrate and a coating layer disposed on the substrate. The substrate includes a folding part overlapping the folding area and having a first thickness, where a groove is defined in the folding part, a plurality of flat parts spaced apart from each other in a first direction with the folding part interposed therebetween and each having a second thickness, and a plurality of edge parts spaced apart from each other in the first direction with the folding part and the flat parts interposed therebetween and each having a third thickness, where the third thickness is greater than the second thickness, and the second thickness is greater than the first thickness.

This application claims priority to Korean Patent Application No. 10-2025-0043857, filed on Apr. 4, 2025, and all the benefits accruing therefrom under 35 U.S.C. §119, the content of which in its entirety is therein incorporated by reference.

### BACKGROUND

### (1) Field

Embodiments of the present disclosure described herein relate to a foldable window, a method of manufacturing the window, and an electronic device including the window, and more particularly, relate to an electronic device including a window in which a substrate is formed in an inclined structure and a polymer resin may be accommodated therein .

### (2) Description of the Related Art

Various types of electronic devices are used to provide image information, and electronic devices including foldable or bendable flexible display panels have recently been developed. Unlike rigid electronic devices, the flexible electronic devices may be variously changed in shape, for example, may be folded, rolled, or bent, and thus may be carried regardless of a size of a displayed screen.

The flexible electronic devices may typically include a window for protecting a display panel or the like without hindering a folding or bending operation.

### SUMMARY

Embodiments of the present disclosure provide a window having improved reliability, a method of manufacturing the window, and an electronic device including the window.

According to an embodiment, a window, in which a folding area, a first non-folding area adjacent to one side of the folding area, and a second non-folding area adjacent to an opposing side of the folding area are defined, includes a substrate and a coating layer disposed on the substrate, wherein the substrate includes a folding part overlapping the folding area and having a first thickness, where a groove is defined in the folding part, a plurality of flat parts spaced apart from each other in a first direction with the folding part interposed therebetween and each having a second thickness, and a plurality of edge parts spaced apart from each other in the first direction with the folding part and the flat parts interposed therebetween and each having a third thickness, and the third thickness is greater than the second thickness, and the second thickness is greater than the first thickness.

In an embodiment, the edge parts may have the third thickness at both ends of the substrate and may be decreased in directions toward the flat parts to have the second thickness at boundaries thereof with the flat parts.

In an embodiment, the flat parts may have the second thickness at boundaries thereof with the edge parts, respectively, and may extend with a constant thickness equal to the second thickness toward the folding part.

In an embodiment, the folding part may have the second thickness at boundaries thereof with the flat parts, may extend to the groove, and may be decreased to the first thickness.

In an embodiment, the groove may be defined concavely toward a lower surface of the substrate.

In an embodiment, the coating layer may have a flat upper surface and may cover the groove.

In an embodiment, he coating layer may include a silicone-based resin.

According to an embodiment, a method of manufacturing a window, in which a folding area, a first non-folding area adjacent to one side of the folding area, and a second non-folding area adjacent to an opposing side of the folding area are defined, includes forming a first photoresist in an edge area of a substrate overlapping a portion of each of the first non-folding area and the second non-folding area, forming an edge part of the substrate by etching the substrate and removing the first photoresist, forming a second photoresist on the edge part of the substrate and a flat part of the substrate which is adjacent to the edge part and overlaps a remainder of the first non-folding area and the second non-folding area except for the edge area, forming a groove in a folding part of the substrate overlapping the folding area by etching the substrate and removing the second photoresist, and forming a coating layer on the substrate to cover the substrate.

In an embodiment, the first photoresist may include a photosensitive material and a dry photosensitive film.

In an embodiment, the forming the first photoresist may include forming a pattern by radiating ultraviolet rays.

In an embodiment, the forming the coating layer may include applying a polymer resin using an inkjet method or a roll squeeze method.

In an embodiment, the method may further include cutting at least a portion of the edge part with a laser.

In an embodiment, the edge part may have a third thickness at both ends of the substrate and may be decreased in a direction toward the flat part to have a second thickness smaller than the third thickness at a boundary thereof with the flat part.

In an embodiment, the flat part may have the second thickness at a boundary thereof with the edge part and may extend constantly at the second thickness toward the folding part.

In an embodiment, the folding part may have the second thickness at a boundary thereof with the flat part, may extend to the groove, and may be decreased to a first thickness.

In an embodiment, the third thickness of the edge part may be a thickness of the substrate, the third thickness may be greater than the second thickness, and the second thickness may be greater than the first thickness.

In an embodiment, the forming the groove in the folding part may include forming the groove concavely toward a lower surface of the substrate.

In an embodiment, the coating layer may have a flat upper surface and may cover the substrate.

In an embodiment, the coating layer may include a silicone-based resin.

According to an embodiment, an electronic device includes a window, which a folding area, a first non-folding area adjacent to one side of the folding area, and a second non-folding area adjacent to an opposing side of the folding area are defined, a display module disposed under the window, and a processor which drives the display module, where the window includes a substrate and a coating layer disposed on the substrate, the substrate includes a folding part overlapping the folding area and having a first thickness, where a groove is defined in the folding part, a plurality of flat parts spaced apart from each other in a first direction with the folding part interposed therebetween and each having a second thickness, and a plurality of edge parts spaced apart from each other in the first direction with the folding part and the flat parts interposed therebetween and each having a third thickness, and the third thickness is greater than the second thickness, and the second thickness is greater than the first thickness.

### BRIEF DESCRIPTION OF THE DRAWINGS

The above and other features of embodiments of the present disclosure will become apparent by describing in detail embodiments thereof with reference to the accompanying drawings, in which:

FIG. 1 is a block diagram of an electronic device according to an embodiment;

FIG. 2 is a schematic view of the electronic device according to an embodiment;

FIG. 3A is a perspective view illustrating the electronic device according to an embodiment;

FIG. 3B is a perspective view illustrating the electronic device according to an embodiment;

FIG. 3C is a plan view illustrating the electronic device according to an embodiment;

FIG. 3D is a perspective view illustrating the electronic device according to an embodiment;

FIG. 4A is a perspective view illustrating the electronic device according to an embodiment;

FIG. 4B is a perspective view illustrating the electronic device according to an embodiment;

FIG. 4C is a perspective view illustrating the electronic device according to an embodiment;

FIG. 5 is an exploded perspective view illustrating the electronic device according to an embodiment;

FIG. 6 is a cross-sectional view illustrating a portion taken along line I-I’ of FIG. 5;

FIG. 7 is a flowchart illustrating a method of manufacturing a window according to an embodiment;

FIG. 8 is a schematic view illustrating an operation of manufacturing a window according to an embodiment;

FIG. 9 is a schematic view illustrating the operation of manufacturing a window according to an embodiment;

FIG. 10 is a schematic view illustrating the operation of manufacturing a window according to an embodiment;

FIG. 11 is a schematic view illustrating the operation of manufacturing a window according to an embodiment;

FIG. 12 is a schematic view illustrating the operation of manufacturing a window according to an embodiment; and

FIG. 13 is a schematic view illustrating the operation of manufacturing a window according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In the specification, the expression that a first component (or area, layer, part, portion, etc.) is “connected with” or “coupled to” a second component means that the first component is directly connected with/coupled to the second component or means that a third component is interposed therebetween.

The same reference numerals refer to the same components. Further, in the drawings, the thickness, the ratio, and the dimension of components are exaggerated for effective description of technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical terms and scientific terms) used in the specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

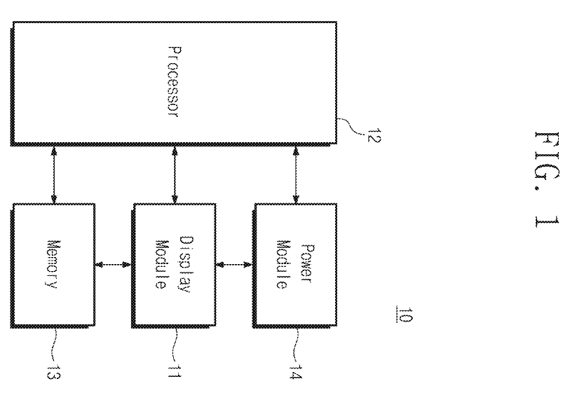

FIG. 1 is a block diagram of an electronic device according to an embodiment. Referring to FIG. 1, an electronic device 10 according to an embodiment may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

Data information used for operations of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device and a power conversion module that converts power supplied by the power supply module to generate power used for the operation of the electronic device 10.

At least one of the components of the electronic device 10 may be included in the display device according to an embodiment. Further, some of individual modules functionally included inside one module may be included inside the display device, and the others thereof may be provided separately from the display device. In an embodiment, for example, the display device may include the display module 11, and the processor 12, the memory 13, and the power module 14 may be provided in the form of other devices in the electronic device 10 rather than the display device.

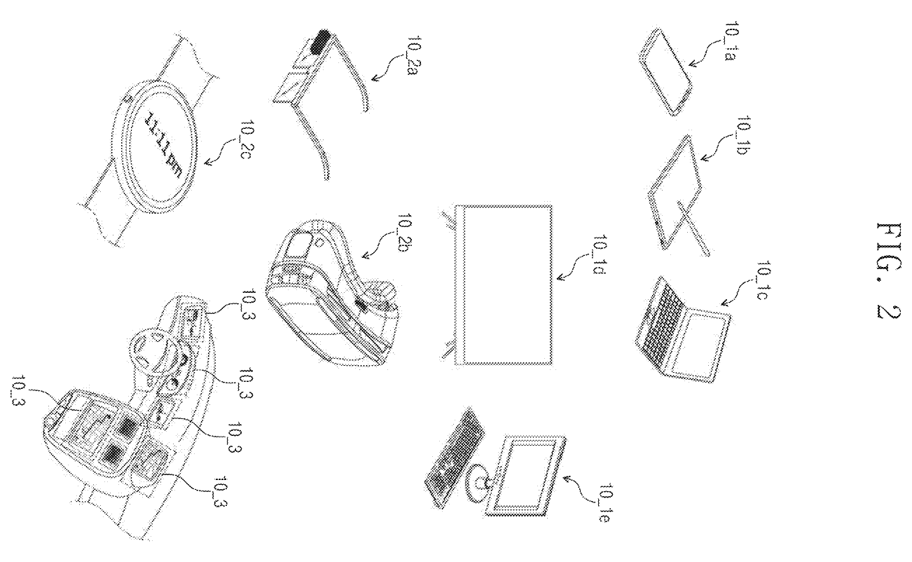

FIG. 2 is a schematic view of the electronic device according to an embodiment.

Referring to FIG. 2, various electronic devices to which the display device according to an embodiment is applied may include an image display electronic device such as a smartphone 10_1a, a tablet personal computer (PC) 10_1b, a laptop computer 10_1c, a television (TV) 10_1d, and a desk monitor 10_1e, a wearable electronic device including a display module such as a smart glasses 10_2a, a head mounted display 10_2b, and a smart watch 10_2c, and a vehicle electronic device 10_3 including a display module such as an instrument panel, a center fascia, a center information display (CID) disposed on a dashboard, and a room mirror display of a vehicle.

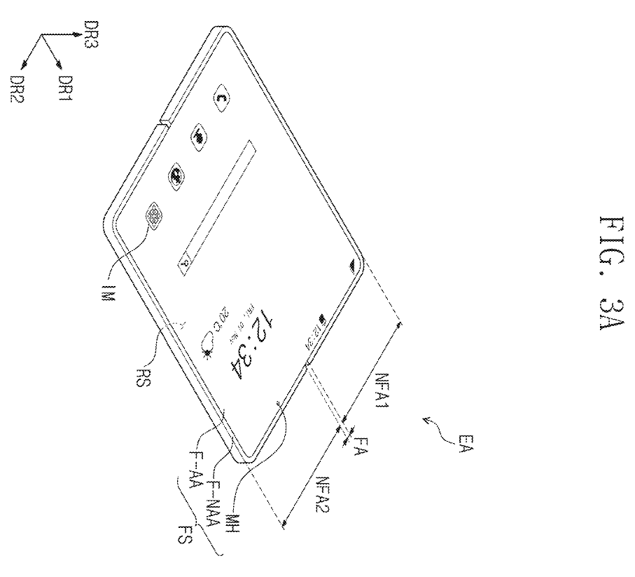

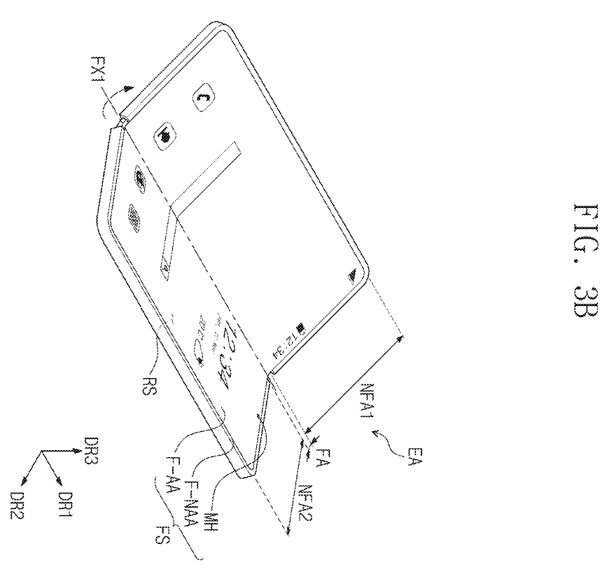

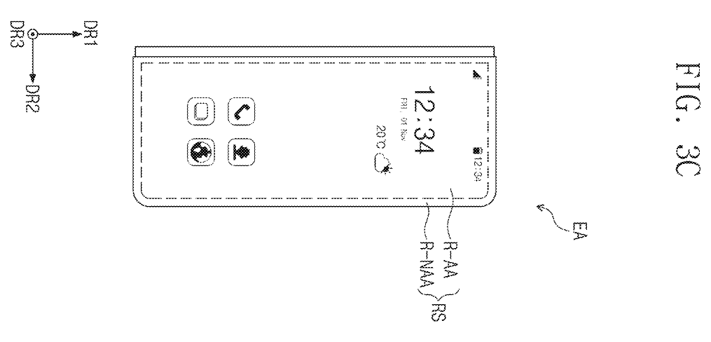

FIG. 3A is a perspective view of a state in which an electronic device EA according to an embodiment is unfolded.

Referring to FIG. 3A, the electronic device EA according to an embodiment may be a device that is activated according to an electrical signal. In an embodiment, for example, the electronic device EA may be a smartphone, a tablet computer, a vehicle navigation system, a game console, or a wearable device, but an embodiment is not limited thereto. FIG. 3A or the like illustrates, by way of example, an embodiment where the electronic device EA is a smartphone.

The electronic device EA may include a first display surface FS defined by a first direction DR1 and a second direction DR2 intersecting the first direction DR1. The electronic device EA may provide an image IM to a user through the first display surface FS. The electronic device EA may display the image IM toward a third direction DR3 with the first display surface FS parallel to each of the first direction DR1 and the second direction DR2. The image IM may include a dynamic image and a static image.

In the specification, the first direction DR1 and the second direction DR2 are perpendicular to each other, and the third direction DR3 may be a normal direction to a plane defined by the first direction DR1 and the second direction DR2. A thickness direction of the electronic device EA may be a direction parallel to the third direction DR3. The thickness direction of the electronic device EA may use the same reference numeral as that of the third direction DR3. A front surface (or an upper surface) and a rear surface (or a lower surface) may be opposite to each other in the third direction DR3, and a normal direction of each of the front surface (or the upper surface) and the rear surface (or the lower surface) may be parallel to the third direction DR3. The front surface (or the upper surface) means a surface adjacent to the first display surface FS, and the rear surface (or the lower surface) means a surface spaced apart from the first display surface FS. Further, the rear surface (or the lower surface) means a surface close to a second display surface RS, which will be described below. An upper side means a direction closer to the first display surface FS, and a lower side means a direction away from the first display surface FS.

A cross section means a surface parallel to the third direction DR3, and a plane means a surface perpendicular to the third direction DR3. A plane means a surface parallel to the plane defined by the first direction DR1 and the second direction DR2.

The directions indicated by the first direction DR1, the second direction DR2, and the third direction DR3 described in the specification are relative concepts and may be changed to other directions. Further, the directions indicated by the first direction DR1, the second direction DR2, and the third direction DR3 may be described as a first direction, a second direction, and a third direction, and the same reference numerals may be used therefor.

In an embodiment, the electronic device EA may sense an external input applied from the outside. The external input may include various types of inputs provided from the outside of the electronic device EA. In an embodiment, for example, the external input may include a contact by a part of a body of the user such as a hand as well as an external input (e.g., hovering) applied close to the electronic device EA or adjacent to the electronic device EA at a predetermined distance. Further, the external input may have various forms such as a force, a pressure, a temperature, and light.

In an embodiment, the electronic device EA may include the first display surface FS and the second display surface RS. The first display surface FS may include a first active area F-AA, a first peripheral area F-NAA, and a sub-area MH. The second display surface RS may be defined as a surface facing at least a portion of the first display surface FS. That is, the second display surface RS may be defined as a portion of the rear surface of the electronic device EA.

The first active area F-AA may be an area that is activated according to an electrical signal. The first active area F-AA may be an area in which the image IM is displayed and various forms of external inputs may be sensed.

The first peripheral area F-NAA may be adjacent to the first active area F-AA. A light transmittance of the first peripheral area F-NAA may be lower than a light transmittance of the first active area F-AA. The first peripheral area F-NAA may have a predetermined color. In an embodiment, the first peripheral area F-NAA may surround the first active area F-AA in a plan view or when viewed in the third direction DR3. Accordingly, a shape of the first active area F-AA may be defined substantially by the first peripheral area F-NAA. However, this is merely an example, and the first peripheral area F-NAA may be disposed adjacent to only one side of the first active area F-AA or may be omitted in another embodiment.

The sub-area MH may sense an external subject received through the display surfaces FS and RS or provide a sound signal such as voice to the outside through the display surfaces FS and RS. An optical signal such as visible light or infrared light may be moved to the sub-area MH.

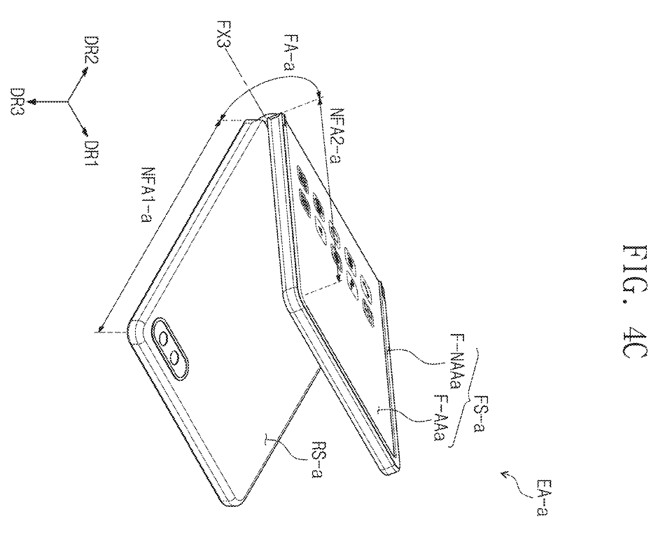

Various electronic modules ELM (see FIG. 5) may be arranged to correspond to the sub-area MH. In an embodiment, for example, the electronic module ELM (see FIG. 5) may include at least one selected from a camera, a speaker, a light sensing sensor, and a heat sensing sensor. The electronic device EA may include the electronic module ELM (see FIG. 5) that captures an external image through visible light passing through the sub-area MH or determines accessibility of an external object through infrared light. The electronic module ELM (see FIG. 5) may include a plurality of components, and is not limited to an embodiment.

In an embodiment, the sub-area MH may be disposed inside the first active area F-AA. However, this is merely an example, and an embodiment is not limited thereto. In another embodiment, for example, the sub-area MH may be surrounded by the first peripheral area F-NAA or may be surrounded by the first active area F-AA and the first peripheral area F-NAA. FIG. 3A and the like illustrate an embodiment in which a single sub-area MH is defined, but not being limited thereto. In another embodiment, the sub-area MH may be provided as a plurality of sub-areas MH.

The electronic device EA according to an embodiment may include at least one folding area FA and a plurality of non-folding areas NFA1 and NFA2 extending from the folding area FA. In an embodiment, for example, the first non-folding area NFA1, the folding area FA, and the second non-folding area NFA2 may be defined in the second direction DR2. The electronic device EA according to an embodiment may include the first non-folding area NFA1 and the second non-folding area NFA2 spaced apart from each other in the second direction DR2 with the folding area FA interposed therebetween. In an embodiment, for example, the first non-folding area NFA1 may be disposed on one side of the folding area FA in the second direction DR2, and the second non-folding area NFA2 may be disposed on an opposing side of the folding area FA in the second direction DR2.

FIG. 3A and the like illustrate the electronic device EA including a single folding area FA according to an embodiment, but an embodiment is not limited thereto, and a plurality of folding areas may be defined in the electronic device EA in another embodiment. For example, the electronic device according to another embodiment may include two or more folding areas and may include three or more non-folding areas arranged with the folding areas interposed therebetween.

FIG. 3B is a perspective view illustrating a folding operation of the electronic device EA according to an embodiment. FIG. 3C is a plan view of a state in which the electronic device EA according to an embodiment is folded. FIG. 3D is a perspective view illustrating a folding operation of the electronic device EA according to an embodiment.

Referring to FIG. 3B, the electronic device EA according to an embodiment may be folded about a first folding axis FX1 extending in the first direction DR1. In a state in which the electronic device EA is folded, the folding area FA may have a predetermined curvature and a predetermined radius of curvature. The electronic device EA may be folded about the first folding axis FX1 so that the first non-folding area NFA1 and the second non-folding area NFA2 face each other and may be changed into an in-folding state to prevent the first display surface FS from being exposed to the outside.

FIG. 3C may be a plan view illustrating the electronic device EA in the in-folding state. Referring to FIG. 3C, in a state in which the electronic device EA according to an embodiment is in the in-folding state, the second display surface RS may be visually recognized by the user. In this state, the second display surface RS may include a second active area R-AA that displays an image. The second active area R-AA may be an area that is activated based on an electrical signal. The second active area R-AA may be an area on which an image is displayed and various types of external inputs may be sensed.

A second peripheral area R-NAA may be adjacent to the second active area R-AA. A light transmittance of the second peripheral area R-NAA may be lower than a light transmittance of the second active area R-AA. The second peripheral area R-NAA may have a predetermined color. The second peripheral area R-NAA may surround the second active area R-AA. Although not illustrated, the electronic device EA may further include a sub-area in which an electronic module including various components is disposed even on the second display surface RS, but the present disclosure is not limited to an embodiment.

Referring to FIG. 3D, the electronic device EA according to an embodiment may be folded about a second folding axis FX2 extending in the first direction DR1. The electronic device EA may be folded about the second folding axis FX2 and changed into an out-folding state so that the first display surface FS is exposed to the outside. In an embodiment, the electronic device EA may be configured to mutually repeat an in-folding operation or an out-folding operation from an unfolding operation, but the present disclosure is not limited thereto.

Although FIGS. 3A-3D illustrate, by way of example, the folding about one folding axis FX1 or FX2, in the electronic device EA according to an embodiment, the number of folding axes and the number of non-folding areas according thereto are not limited thereto. In another embodiment, for example, the electronic device EA may be folded about a plurality of folding axes so that the first display surface FS and the second display surface RS are folded to partially face each other. Further, FIGS. 3A-3D illustrate an embodiment where the first folding axis FX1 and the second folding axis FX2 are parallel to long sides of the electronic device EA, but an embodiment is not limited thereto, and the first folding axis FX1 and the second folding axis FX2 may be parallel to short sides of the electronic device EA.

In an embodiment of the electronic device EA, as illustrated in FIG. 3A and the like, the first non-folding area NFA1 and the second non-folding area NFA2 may be defined as portions having the display surfaces FS and RS parallel to the plane defined by the first direction DR1 and the second direction DR2 in a folded state, and the folding area FA may be defined as an area between the first non-folding area NFA1 and the second non-folding area NFA2. The folding area FA may include a curved surface that is curved to have a predetermined curvature in a folded state.

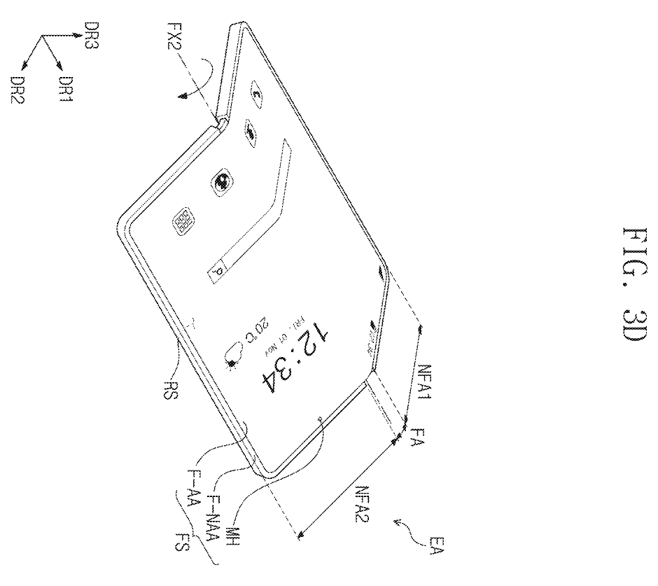

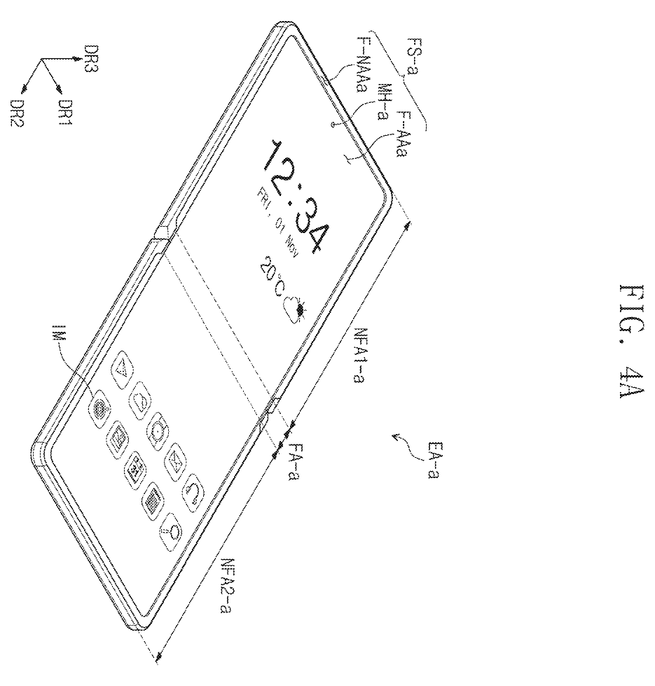

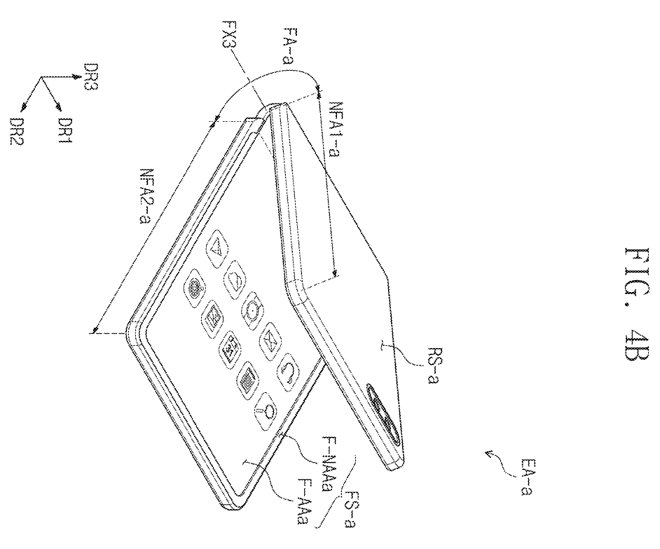

FIGS. 4A-4C are perspective views illustrating an electronic device EA-a according to an embodiment of the present disclosure. FIG. 4A is a perspective view illustrating an unfolded state of the electronic device EA-a. FIGS. 4B and 4C are perspective views illustrating a folding operation of the electronic device EA-a. FIG. 4B is a perspective view illustrating an in-folding operation of the electronic device EA-a illustrated in FIG. 4A. FIG. 4C is a perspective view illustrating an out-folding operation of the electronic device EA-a illustrated in FIG. 4A.

Referring to FIGS. 4A-4C, an embodiment of the electronic device EA-a may be folded about a third folding axis FX3 parallel to the first direction DR1. An extension direction of the third folding axis FX3 may be parallel to an extension direction of short sides of the electronic device EA-a.

The electronic device EA-a may be divided into a folding area FA-a, a first non-folding area NFA1-a adjacent to one side of the folding area FA-a, and a second non-folding area NFA2-a adjacent to the other side of the folding area FA-a. The first non-folding area NFA1-a and the second non-folding area NFA2-a may be spaced apart from each other with the folding area FA-a interposed therebetween.

The folding area FA-a may be an area folded or foldable about the third folding axis FX3. In a state in which the electronic device EA-a is folded, the folding area FA-a may have a predetermined curvature and a predetermined radius of curvature. The first non-folding area NFA1-a and the second non-folding area NFA2-a may face each other, and the electronic device EA-a may be in-folded to prevent a display surface FS-a from being exposed to the outside.

Referring to FIG. 4A, in an embodiment, in a state in which the electronic device EA-a is in an unfolded state (i.e., a non-folded state), the display surface FS-a may be visually recognized by the user. As described above with reference to FIGS. 3A-3D, the display surface FS-a of the electronic device EA-a may include an active area F-AAa, a peripheral area F-NAAa, and a sub-area MH-a. The active area F-AAa may be an area in which the image IM is displayed and various forms of external inputs may be sensed.

Referring to FIG. 4B, in a state in which the electronic device EA-a according to an embodiment is in-folded, a rear surface RS-a may be visually recognized by the user. In an embodiment, for example, the rear surface RS-a may function as a second display surface that displays an image in this state. Further, the sub-area in which an electronic module including various components is disposed may also be provided even on the rear surface RS-a.

Referring to FIG. 4C, the electronic device EA-a may be folded about the third folding axis FX3 and changed into an out-folding state in which one area of the rear surface RS-a overlapping the first non-folding area NFA1-a and the other area of the rear surface RS-a overlapping the second non-folding area NFA2-a face each other.

FIG. 5 is an exploded perspective view illustrating the electronic device EA according to an embodiment. Hereinafter, any repetitive detailed description of the same or like elements of the electronic device EA as those of the electronic device EA-a described above with reference to FIGS. 4A-4C will be omitted or simplified.

Referring to FIG. 5, an embodiment of the electronic device EA may include the electronic module ELM and a display device DD. Further, the electronic device EA may further include a housing HAU. In an embodiment, the display device DD may include a display module DM and a window WM disposed on the display module DM. The display module DM may have substantially the same component as the display module 11 (see FIG. 1) described in FIG. 1. A module area DM-MH may be defined in the display device DD, and the electronic module ELM may be disposed to correspond to the module area DM-MH.

The image IM (see FIG. 3A) generated in the display module DM may be provided to the user while passing through the window WM. The window WM may be folded about at least one folding axis FX1 or FX2 (see FIGS. 3B and 3D).

The display device DD may further include an upper adhesive layer AP-R. The upper adhesive layer AP-R may be disposed between the display module DM and the window WM. The display module DM and the window WM may be coupled to each other through the upper adhesive layer AP-R. The upper adhesive layer AP-R may include a pressure sensitive adhesive (PSA), an optically clear adhesive film (OCA), or an optically clear adhesive resin layer (OCR).

The display module DM may display an image based on an electric signal. The display module DM may transmit/receive information on an external input. A display area DM-DA and a non-display area DM-NDA may be defined in the display module DM. Further, the module area DM-MH may be defined in the display module DM.

The display area DM-DA may be defined as an area that emits an image provided from the display module DM. The display area DM-DA of the display module DM may correspond to at least a portion of the first active area F-AA (see FIG. 3A).

A driving circuit, a driving wiring line, or the like for driving the display area DM-DA may be disposed in the non-display area DM-NDA. The non-display area DM-NDA may be adjacent to the display area DM-DA. In an embodiment, for example, the non-display area DM-NDA may surround the display area DM-DA. However, this is merely an example, the non-display area DM-NDA may be defined in various shapes, and the present disclosure is not limited to an embodiment.

The module area DM-MH may correspond to the sub-area MH illustrated in FIG. 3A. An optical signal may move through the module area DM-MH. The module area DM-MH may be disposed inside the display area DM-DA. However, this is merely an example, and the present disclosure is not limited to an embodiment.

The electronic module ELM may be disposed to correspond to the module area DM-MH. The electronic module ELM may be an electronic component that outputs or receives an optical signal. In an embodiment, for example, the electronic module ELM may include a camera module and/or a proximity sensor. The camera module may capture an external image through the module area DM-MH. However, an embodiment is not limited thereto, and the electronic module ELM may further include a built-in module and/or an external module. The built-in module may include a sensor module, an antenna module, and an audio output module. The external module may include a light module and a communication module.

The display module DM may include a folding display part FP-D and non-folding display parts NFP1-D and NFP2-D. The folding display part FP-D may be a part corresponding to the folding area FA (see FIG. 3A), and the non-folding display parts NFP1-D and NFP2-D may be parts corresponding to the non-folding areas NFA1 and NFA2 (see FIG. 3A).

The housing HAU may include a material having a high rigidity. In an embodiment, for example, the housing HAU may include a plurality of frames and/or plates including or made of glass, plastic, or metal. The housing HAU may provide a predetermined accommodation space. The display module DM may be accommodated inside the accommodation space and protected from an external impact.

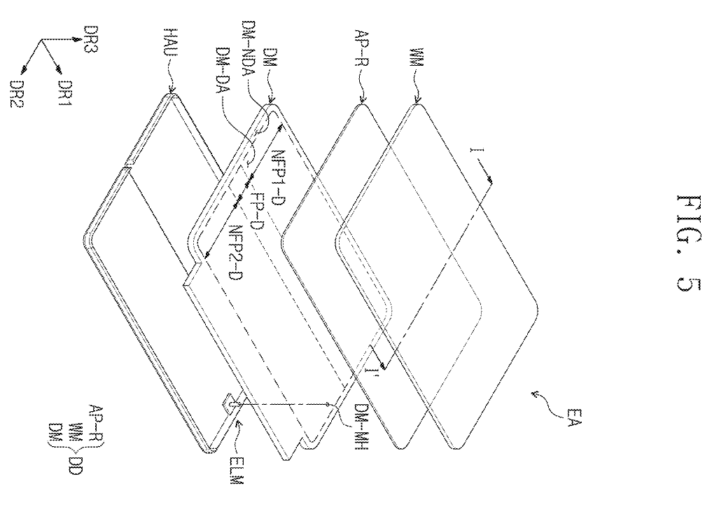

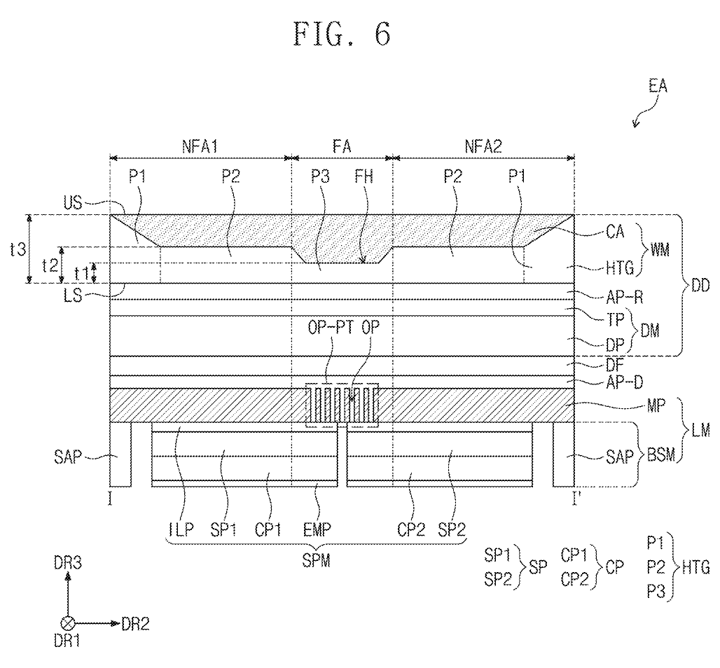

FIG. 6 is a cross-sectional view illustrating a portion taken along line I-I’ of FIG. 5. FIG. 6 may be a cross-sectional view illustrating the electronic device EA according to an embodiment. In FIG. 6, for convenience of illustration and description, the housing HAU (see FIG. 5) is omitted.

Referring to FIG. 6, an embodiment of the electronic device EA may further include a lower module LM, a lower adhesive layer AP-D, and a lower protective film DF. The lower module LM, the lower adhesive layer AP-D, and the lower protective film DF may be arranged between the display device DD and the housing HAU (see FIG. 5).

The lower module LM may be disposed below the display module DM. The lower module LM may include a support plate MP and a lower support member BSM. A configuration of the lower module LM illustrated in FIG. 6 is merely an example, and a combination of components included in the lower module LM in the electronic device EA according to an embodiment may be changed depending on a size of the electronic device EA, a shape of the electronic device EA, or operating characteristics of the electronic device EA.

The support plate MP may include a metal material or a polymer material. In an embodiment, for example, the support plate MP may be formed to include stainless steel, aluminum, or an alloy thereof. In another embodiment, the support plate MP may include or be formed of a polymer material. A plurality of openings OP may be defined in the support plate MP. The support plate MP may include an opening pattern OP-PT in which the plurality of openings OP are defined. The opening pattern OP-PT may be formed in the folding area FA.

The lower support member BSM may include a support member SPM and a filling part SAP. On a plane or in a plan view, the support member SPM may overlap most areas of the display module DM. The filling part SAP may be disposed outside the support member SPM and may overlap an exterior of the display module DM.

The support member SPM may include at least one of a support layer SP, a cushion layer CP, a shielding layer EMP, and an interlayer joining layer ILP. A configuration of the support member SPM illustrated in FIG. 6 is merely an example, and an embodiment is not limited thereto. In another embodiment, for example, some of the support layer SP, the cushion layer CP, the shielding layer EMP, and the interlayer joining layer ILP may be omitted, a laminated order thereof may be modified to a different order from that of FIG. 6, or an additional component in addition to the illustrated components may be further included in the support member SPM.

The support layer SP may include a metal material or a polymer material. The support layer SP may be disposed below the support plate MP. In an embodiment, for example, the support layer SP may be a thin metal substrate. The support layer SP may include a first sub-support layer SP1 and a second sub-support layer SP2 spaced apart from each other in the second direction DR2. The first sub-support layer SP1 and the second sub-support layer SP2 may be spaced apart from each other in areas corresponding to the folding axes FX1 and FX2 (see FIGS. 3B and 3D). The support layer SP may be provided as the first sub-support layer SP1 and the second sub-support layer SP2 spaced apart from the folding area FA, thereby improving folding characteristics of the electronic device EA.

The cushion layer CP may be disposed below the support layer SP. The cushion layer CP may prevent a pressing phenomenon and plastic deformation of the support plate MP due to an external impact and an external force. The cushion layer CP may improve impact resistance of the electronic device EA. The cushion layer CP may include an elastomer such as sponge, foam, or urethane resin. Further, the cushion layer CP may be formed to include at least one selected from an acryl-based polymer, a urethane-based polymer, a silicone-based polymer, and an imide-based polymer. However, this is merely an example, and an embodiment is not limited thereto.

The cushion layer CP may include a first sub-cushion layer CP1 and a second sub-cushion layer CP2 spaced apart from each other in the second direction DR2. The first sub-cushion layer CP1 and the second sub-cushion layer CP2 may be spaced apart from each other in portions corresponding to the folding axes FX1 and FX2 (see FIGS. 3B and 3D). The cushion layer CP may be provided as the first sub-cushion layer CP1 and the second sub-cushion layer CP2 spaced apart from the folding area FA, thereby improving folding characteristics of the electronic device EA.

The shielding layer EMP may be an electromagnetic wave shielding layer or a heat dissipating layer. Further, the shielding layer EMP may function as a joining layer.

The interlayer joining layer ILP may join components of the support plate MP and the support member SPM. The interlayer joining layer ILP may be provided in the form of a joining resin layer or an adhesive tape. FIG. 6 illustrates an embodiment where the interlayer joining layer ILP is provided as two components spaced apart from each other in the areas corresponding to the folding axes FX1 and FX2 (see FIGS. 3B and 3D), but an embodiment is not limited thereto. In another embodiment, the interlayer joining layer ILP may be provided as one layer that is not spaced apart from the areas corresponding to the folding axes FX1 and FX2 (see FIGS. 3B and 3D).

The filling part SAP may be disposed outside the support layer SP and the cushion layer CP. The filling part SAP may be disposed between the support plate MP and the housing HAU (see FIG. 5). The filling part SAP may fill a space between the support plate MP and the housing HAU (see FIG. 5) and fix the support plate MP to the housing HAU.

The lower protective film DF may be disposed between the display module DM and the support plate MP. The lower protective film DF may be a component disposed under the display module DM to protect a rear surface of the display module DM. The lower protective film DF may entirely overlap the display module DM. The lower protective film DF may include a polymer material. In an embodiment, for example, the lower protective film DF may be a polyimide film or a polyethylene terephthalate film. However, this is merely an example, and the lower protective film DF is not limited thereto.

The lower adhesive layer AP-D may be disposed between the support plate MP and the lower protective film DF. The support plate MP and the lower protective film DF may be coupled to each other through the lower adhesive layer AP-D. The lower adhesive layer AP-D may include a pressure sensitive adhesive (PSA), an optically clear adhesive film (OCA), or an optically clear adhesive resin layer (OCR). However, this is merely an example, and an embodiment is not limited thereto. In another embodiment, the lower adhesive layer AP-D may be omitted.

The display module DM may include a display panel DP and an input sensing unit TP disposed on the display panel DP. The display panel DP may substantially generate an image. The display panel DP according to an embodiment may be folded about the folding axes FX1 and FX2 (see FIGS. 3B and 3D).

The display panel DP according to an embodiment of the present disclosure may be a light emitting display panel, but the present disclosure is not particularly limited thereto. In an embodiment, for example, the display panel DP may be an organic light emitting display panel, an inorganic light emitting display panel, a micro light emitting diode (LED) display panel, or a nano LED display panel. A light emitting layer of the organic light emitting display panel may include an organic light emitting material. A light emitting layer of the inorganic light emitting display panel may include a quantum dot, a quantum rod, and the like. A light emitting layer of the micro LED display panel may include a micro LED. A light emitting layer of the nano LED display panel may include a nano LED.

The input sensing unit TP may sense an external input, convert the sensed external input into a predetermined input signal, and provide the input signal to the display panel DP. In an embodiment, for example, the input sensing unit TP may be a touch sensing unit that senses a touch. The input sensing unit TP may detect or recognize a direct touch of the user, an indirect touch of the user, a direct touch of an object, an indirect touch of the object, or the like.

The input sensing unit TP may sense at least one selected from a position of a touch applied from the outside and a strength (pressure) of the touch. In an embodiment, the input sensing unit TP may have various structures or may include or be formed of various materials, and the present disclosure is not limited to an embodiment. In an embodiment, for example, the input sensing unit TP may sense an external input in a capacitive manner. The display panel DP may receive the input signal from the input sensing unit TP and generate an image corresponding to the input signal.

The window WM may include a substrate HTG and a coating layer CA disposed on the substrate HTG. The window WM may be defined as the folding area FA, the first non-folding area NFA1 adjacent to one side of the folding area FA, and the second non-folding area NFA2 adjacent to the other side of the folding area FA.

The substrate HTG may include an optically transparent insulating material. In an embodiment, for example, the substrate HTG may include glass.

A lower surface LS of the substrate HTG may have a flat surface. The substrate HTG may be disposed on the upper adhesive layer AP-R. The substrate HTG may be in direct contact with the upper adhesive layer AP-R. The image IM (see FIG. 3A) generated by the display module DM may pass through the window WM and be provided to the user.

The substrate HTG may include a folding part P3, a plurality of flat parts P2, and a plurality of edge parts P1. The folding part P3 may overlap the folding area FA and have a first thickness t1. The plurality of flat parts P2 may be spaced apart from each other in the second direction DR2 with the folding part P3 interposed therebetween and each may have a second thickness t2. The plurality of edge parts P1 may be spaced apart from each other in the second direction DR2 with the folding part P3 and the flat parts P2 interposed therebetween and each may have a third thickness t3. Here, the third thickness t3 may be a greatest thickness of each of the plurality of edge parts P1. The third thickness t3 may be greater than the second thickness t2, and the second thickness t2 may be greater than the first thickness t1.

Each of the plurality of edge parts P1 may have the third thickness t3 at both ends of the substrate HTG and may be decreased to the second thickness t2 in a direction toward the flat parts P2.

The plurality of flat parts P2 may have the second thickness t2 at points in contact with (or at boundaries thereof with) the plurality of edge parts P1, respectively, and may extend with a constant thickness equal to the second thickness t2 toward the folding part P3.

A groove FH may be defined in the folding part P3. The groove FH may be defined to be concave toward a bottom surface of the substrate HTG. The groove FH may be formed by removing a portion from an upper surface of the folding part P3. FIG. 6 illustrates, by way of example, an embodiment where the groove FH has a shape corresponding to a portion of a trapezoidal shape, but the shape of the groove FH according to an embodiment of the present disclosure is not limited thereto. In an embodiment, for example, the groove FH may have a shape corresponding to a portion of a semicircle, a rectangle, or a triangle.

The folding part P3 may have the second thickness t2 at a point in contact with each of the plurality of flat parts P2, may extend to the groove FH, and may be decreased to the first thickness t1.

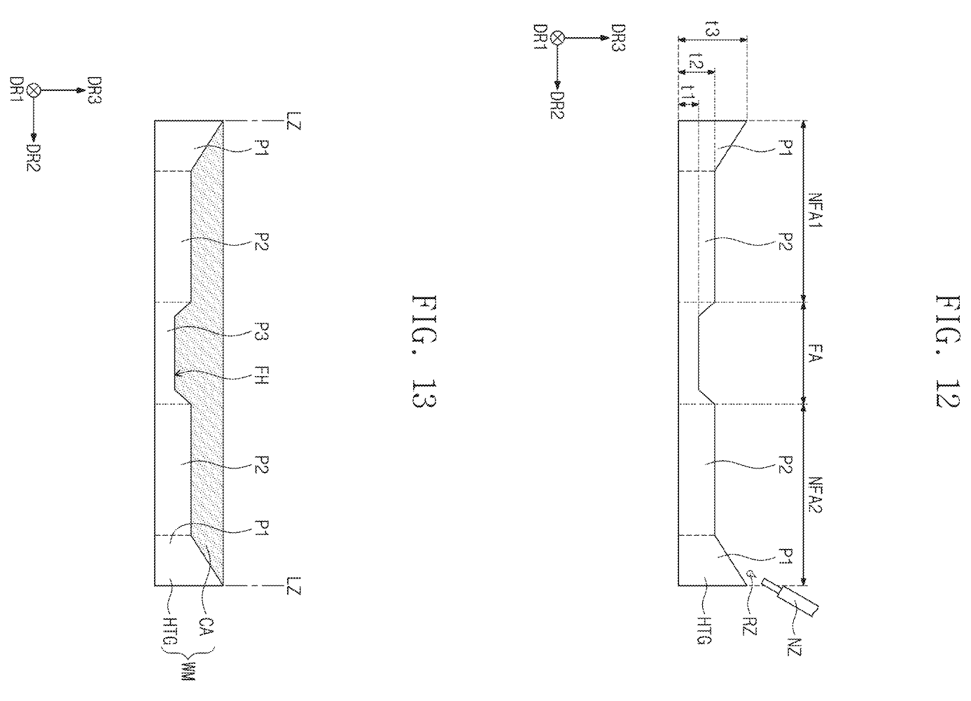

A polymer resin disposed on the substrate HTG and defining the window WM together with the substrate HTG may have a greater surface tension as the number of parts in contact with air becomes greater. Further, the surface tension is relatively greater at an edge than in an inside thereof, and thus, the edge may be contracted more than the center. As a contraction coefficient becomes greater, the polymer resin disposed at the edge is contracted and inclined when the polymer resin is cured, and to compensate for this, an additional process such as a laser cut of removing the inclined portion may be desired to be performed. According to an embodiment of the present disclosure, as the thickness of the folding part P3 is smaller than the thickness of the edge part P1 and the thickness of the flat part P2, the substrate HTG may be formed in an inclined structure. The substrate HTG may accommodate a polymer resin RZ (see FIG. 12) forming the coating layer CA. Thus, when the polymer resin RZ (see FIG. 12) is applied to the substrate HTG and cured, the polymer resin RZ (see FIG. 12) is in contact with the substrate HTG and thus there may be less contact with the air, and the polymer resin RZ is cured inside the substrate HTG in a fixed state and thus there may be less contraction. That is, the polymer resin RZ (see FIG. 12) may be cured while fixed inside the substrate HTG, and thus the inclination may not occur. Therefore, the electronic device EA (see FIG. 3A) having improved reliability may be provided. Further, a method of manufacturing the window WM may be further simplified.

The coating layer CA may be disposed on the substrate HTG to cover the groove FH. The coating layer CA may include at least one selected from an acrylic resin, an epoxy resin, a silicone resin, a urethane resin, a urethane acrylic resin, a hybrid sol gel, and a siloxane-based resin.

An upper surface US of the coating layer CA may be a flat surface. The coating layer CA may cover and protect the substrate HTG.

According to an embodiment of the present disclosure, the coating layer CA may include or be made of a silicone resin. The silicone resin has a relatively low contraction coefficient compared to the acryl-based resin, and thus when the polymer resin RZ (see FIG. 12) is applied to the substrate HTG and cured, a phenomenon in which an inclination occurs at the edge part P1 and an end of the edge part P1 may be effectively prevented. Further, an additional process such as a laser cut is not performed, and thus a process time may be substantially reduced.

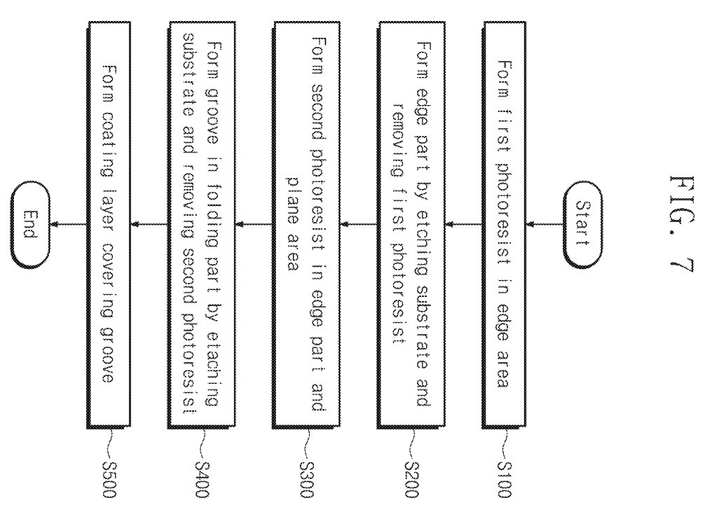

FIG. 7 is a flowchart illustrating a method of manufacturing a window according to an embodiment. FIGS. 8-13 are schematic views illustrating operations of manufacturing a window according to an embodiment. In the description of FIGS. 8-13, the same or like components as those described above are designated by the same reference numerals, and any repetitive detailed description thereof will be omitted.

Referring to FIGS. 7-13, the window WM according to an embodiment may be manufactured by the method of manufacturing a window according to an embodiment.

The method of manufacturing a window according to an embodiment may include operation S100 of forming a first photoresist PR1 in an edge area D1 overlapping a portion of each of the first non-folding area NFA1 and the second non-folding area NFA2 of the substrate HTG, operation S200 of forming the edge part P1 by etching the substrate HTG and removing the first photoresist PR1, operation S300 of forming a second photoresist PR2 in the edge part P1 and a plane area adjacent to the edge part P1 and overlapping the remainder except for the edge area D1 in each of the first non-folding area NFA1 and the second non-folding area NFA2, operation S400 of forming the groove FH in the folding part P3 overlapping the folding area FA by etching the substrate HTG and removing the second photoresist PR2, and operation S500 of forming the coating layer CA that is disposed on the substrate HTG and covers the groove FH.

In an embodiment, the method of manufacturing a window may further include an operation of cutting at least a portion of the edge part P1 with a laser LZ.

Referring to FIGS. 7 and 8, in an embodiment of the method of manufacturing a window, the first photoresist PR1 may be formed in the edge area D1 (S100). The edge area D1 may overlap a portion of each of the first non-folding area NFA1 and the second non-folding area NFA2.

The first photoresist PR1 may include a photosensitive material and a dry photosensitive film. The photosensitive material means a material of which chemical properties are changed in response to light. The dry photosensitive film is a photoresist provided in a film form rather than a liquid form.

Operation S100 of forming the first photoresist PR1 may include an operation of forming a pattern by radiating ultraviolet rays. The photoresist is a chemical substance whose properties are changed in response to light and may be used in a photolithography process. The photolithography process may use characteristics of the photoresist.

The first photoresist PR1 has chemical characteristics changed by light, and may become hard or, conversely, easily melt when receiving light, depending on a type thereof. As only the weakened part may be selectively removed using these characteristic changes, a part to be used as a circuit and a part not to be used as the circuit may be distinguished from each other, and thus a fine circuit pattern may be formed.

The first photoresist PR1 may be classified into a positive type and a negative type. The positive type has characteristics in which a light-received portion is dissolved in a developer, the negative type has characteristics in which a non-lighted portion is dissolved, and thus the positive type and the negative type may be selectively used as desired.

Referring to FIGS. 7, 8, and 9, in an embodiment of the method of manufacturing a window, the edge part P1 may be formed by etching the substrate HTG and removing the first photoresist PR1 (S200).

The etching is a process in which only a desired portion is left and an undesired portion part is cut off. In this process, the first photoresist PR1 may protect a material under the corresponding position such that the material is not etched when the etching process is performed.

That is, when an etching material EM is applied, a portion not overlapping the first photoresist PR1 may be removed, and a portion overlapping the first photoresist PR1 may be partially etched.

Thus, the edge part P1 may be formed in the edge area D1.

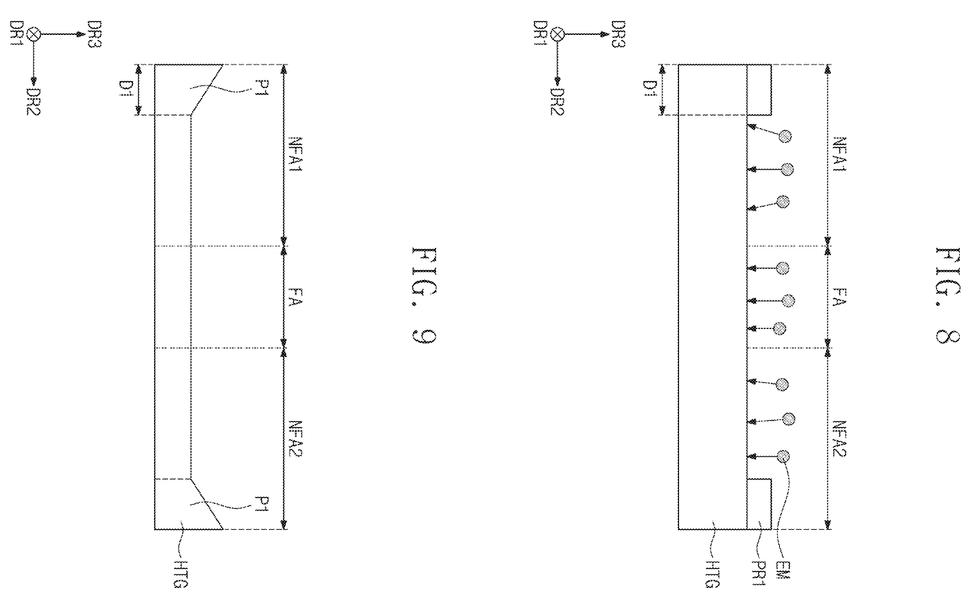

Referring to FIGS. 7 and 10, in an embodiment of the method of manufacturing a window, the second photoresist PR2 may be formed in the edge part P1 and the plane area (S300). The second photoresist PR2 may be formed not to overlap the folding area FA. In the description of FIG. 10, the same or like components as those described above are designated by the same reference numerals, and any repetitive detailed description thereof will be omitted.

The plane area may be adjacent to the edge part P1 and may overlap the remainder except for the edge area D1 of each of the first non-folding area NFA1 and the second non-folding area NFA2. The remainder of the first non-folding area NFA1 and the second non-folding area NFA2 may be an area obtained by excluding the edge area D1 from the first non-folding area NFA1 and the second non-folding area NFA2.

The second photoresist PR2 may include substantially the same material as the first photoresist PR1 (see FIG. 8).

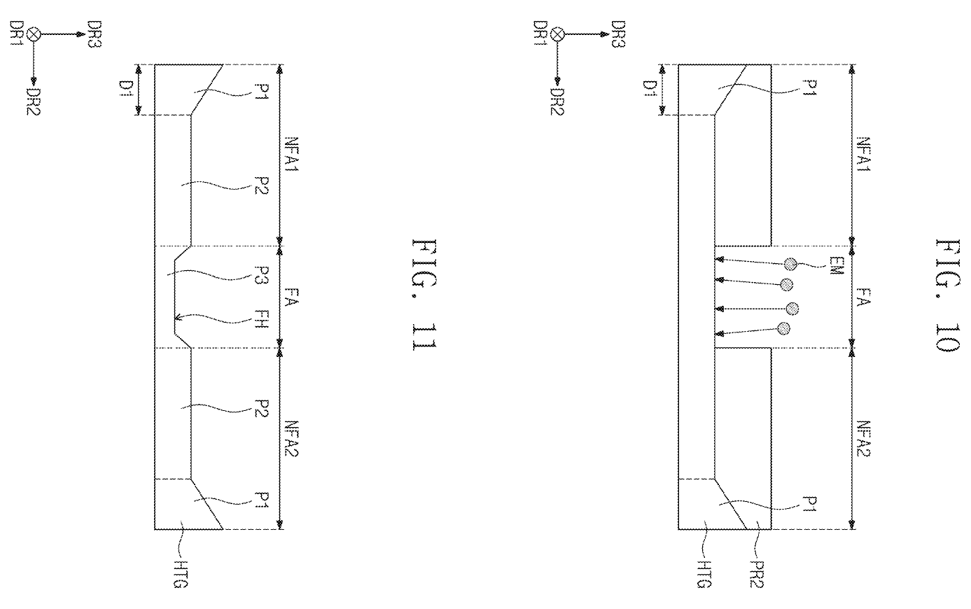

Referring to FIGS. 7, 10, and 11, in an embodiment of the method of manufacturing a window, the groove FH may be formed in the folding part P3 by etching the substrate HTG and removing the second photoresist PR2 (S400). In the description of FIG. 11, the same or like components as those described above are designated by the same reference numerals, and any repetitive detailed description thereof will be omitted.

When the etching material EM is applied, the groove FH may be formed in a portion not having the second photoresist PR2 by removing a portion of the substrate HTG, and a portion having the second photoresist PR2 may not be etched.

The groove FH may be defined concavely toward the lower surface LS (see FIG. 6) of the substrate HTG. A shape of the groove FH may be determined based on the etching material EM. The shape of the groove FH may be determined based on a type, a concentration, an etching time, and an etching method of the used etching material EM. The etching method may include a dry method or a wet method. In an embodiment where the wet etching method is applied, a side wall of the groove FH may be formed in a curved shape depending on diffusion characteristics of the etching solution. In an embodiment where the dry etching process is applied, the side wall of the groove FH may be formed relatively vertically due to anisotropic etching characteristics.

The groove FH may be formed by removing the portion from the upper surface of the folding part P3. FIG. 6 illustrates, by way of example, an embodiment by applying the wet etching method, the groove FH has a shape corresponding to a portion of a trapezoidal shape, but the shape of the groove FH according to an embodiment of the present disclosure is not limited thereto.

Referring to FIGS. 8 and 12, in an embodiment of the method of manufacturing a window, the coating layer CA covering the groove FH may be formed (S500).

The polymer resin RZ may be ultraviolet (UV)-cured to prepare the coating layer CA. The polymer resin RZ may be a photocurable material cured by light. The polymer resin RZ may be provided through a nozzle NZ. The polymer resin RZ may include at least one selected from a urethane acrylate-based resin, an epoxy-based resin, and a silicone-based resin.

Operation S500 of forming the coating layer CA may include an operation of applying the polymer resin RZ using an inkjet method or a roll squeeze method.

The inkjet method may include a method of selectively applying a liquid resin to a surface of the substrate HTG by spraying the liquid resin through the fine nozzle NZ. In the inkjet method, an application position and pattern may be precisely controlled in a non-contact manner, and the coating layer CA having a multi-layer structure may be formed as desired.

Further, the roll squeeze method may include a method of uniformly applying the polymer resin RZ at a certain thickness using a roller. In the roll squeeze method, after the polymer resin RZ may be distributed on the substrate HTG, the polymer resin RZ may come into close contact with the surface of the substrate HTG using a pressing roller and may be maintained a uniform thickness.

According to an embodiment of the present disclosure, as the thickness of the folding part P3 is smaller than the thickness of the edge part P1 and the thickness of the flat part P2, the substrate HTG may be formed in an inclined structure. The substrate HTG may accommodate the polymer resin RZ forming the coating layer CA. Thus, when the polymer resin RZ is applied to the substrate HTG and cured, the polymer resin RZ is in contact with the substrate HTG and thus there may be less contact with the air, and the polymer resin RZ is cured inside the substrate HTG in a fixed state and thus there may be less contraction. Thus, an embodiment of the method for manufacturing the window WM having improved reliability and the electronic device EA (see FIG. 3A) including the window WM may be provided.

In a case where the inclined structure described above is not provided, an open area in contact with a lot of air may be quickly dried, the polymer resin RZ may be further contracted due to an influence of the surface tension, and thus the coating layer CA disposed on the edge part P1 may be deformed. That is, a non-uniform phenomenon or an inclined surface may occur in the coating layer CA disposed on the edge part P1, a laser cutting process may be performed to remove the inclined surface, and thus a process time may be increased. However, according to an embodiment of the present disclosure, the substrate HTG may be formed in an inclined structure as the first thickness t1 of the folding part P3 is smaller than the third thickness t3 of the edge part P1 and the second thickness t2 of the flat part P2. The substrate HTG may accommodate the polymer resin RZ forming the coating layer CA. Thus, when the polymer resin RZ is applied to the substrate HTG and cured, the polymer resin RZ is in contact with the substrate HTG and thus there may be less contact with the air, and the polymer resin RZ is cured inside the substrate HTG in a fixed state and thus there may be less contraction. Therefore, the non-uniform phenomenon and the inclined surface may be effectively prevented or substantially removed. Accordingly, the laser cutting process may be omitted, and thus a window manufacturing process may be simplified.

Referring to FIGS. 6 and 8-13, an embodiment of the method of manufacturing the window WM may optionally further include an operation of cutting at least a portion of the edge part P1 with the laser LZ.

The edge part P1 may be partially cut by the laser LZ. FIG. 13 illustrates, by way of example, an embodiment where the laser LZ is radiated in an opposite direction to the third direction DR3 according to a side surface of the substrate HTG, but a range of the laser cut according to an embodiment of the present disclosure is not limited thereto. In an embodiment, for example, when viewed on a plane, the laser LZ may be radiated onto all areas inside the edge part P1.

In embodiments of the present disclosure, as described above, a thickness of a third part is greater than a thickness of a second part, the thickness of the second part is greater than a thickness of a first part, and thus a substrate may be formed in an inclined structure. The substrate may accommodate a polymer resin forming a coating layer. Thus, when the polymer resin is applied to the substrate and cured, the polymer resin is in contact with the substrate and thus there is less contact with air, and the polymer resin is cured inside the substrate in a fixed state and thus there may be less contraction. Thus, a non-uniform phenomenon and an inclined surface of an edge part may be effectively prevented or substantially removed. Thus, an electronic device having improved reliability may be provided.

In such embodiments, as described above, a coating layer may include or be made of a silicone resin. The silicone resin has a relatively low contraction coefficient compared to an acryl-based resin, and thus when the polymer resin is applied to the substrate and cured, a phenomenon in which an inclination occurs at an end of the edge part may be effectively prevented. Accordingly, an additional process such as a laser cut is not performed, and thus a process time may be reduced. Thus, a window manufacturing process may be simplified.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A window in which a folding area, a first non-folding area adjacent to one side of the folding area, and a second non-folding area adjacent to an opposite side of the folding area are defined, the window comprising:
a substrate; and
a coating layer disposed on the substrate,
wherein the substrate includes:
a folding part overlapping the folding area and having a first thickness, wherein a groove is defined in the folding part;
a plurality of flat parts spaced apart from each other in a first direction with the folding part interposed therebetween and each having a second thickness; and
a plurality of edge parts spaced apart from each other in the first direction with the folding part and the flat parts interposed therebetween and each having a third thickness, and
wherein the third thickness is greater than the second thickness, and the second thickness is greater than the first thickness.

2. The window of claim 1, wherein the edge parts have the third thickness at both ends of the substrate and are decreased in directions toward the flat parts to have the second thickness at boundaries thereof with the flat parts.

3. The window of claim 1, wherein the flat parts have the second thickness at boundaries thereof with edge parts, respectively, and extend with a constant thickness equal to the second thickness toward the folding part.

4. The window of claim 1, wherein the folding part has the second thickness at boundaries thereof with the flat parts, extends to the groove, and is decreased to the first thickness.

5. The window of claim 1, wherein the groove is defined concavely toward a lower surface of the substrate.

6. The window of claim 1, wherein the coating layer has a flat upper surface and covers the groove.

7. The window of claim 1, wherein the coating layer includes a silicone-based resin.

8. A method of manufacturing a window in which a folding area, a first non-folding area adjacent to one side of the folding area, and a second non-folding area adjacent to an opposing side of the folding area are defined, the method comprising:
forming a first photoresist in an edge area of a substrate overlapping a portion of each of the first non-folding area and the second non-folding area;
forming an edge part of the substrate by etching the substrate and removing the first photoresist;
forming a second photoresist on the edge part of the substrate and a flat part of the substrate which is adjacent to the edge part and overlaps a remainder of the first non-folding area and the second non-folding area except for the edge area;
forming a groove in a folding part of the substrate overlapping the folding area by etching the substrate and removing the second photoresist; and
forming a coating layer on the substrate to cover the substrate.

9. The method of claim 8, wherein the first photoresist includes a photosensitive material and a dry photosensitive film.

10. The method of claim 8, wherein the forming the first photoresist includes forming a pattern by radiating ultraviolet rays.

11. The method of claim 8, wherein the forming the coating layer includes applying a polymer resin using an inkjet method or a roll squeeze method.

12. The method of claim 8, further comprising:
cutting at least a portion of the edge part with a laser.

13. The method of claim 8, wherein the edge part has a third thickness at both ends of the substrate and is decreased in a direction toward the flat part to have a second thickness smaller than the third thickness at a boundary thereof with the flat part.

14. The method of claim 13, wherein the flat part has the second thickness at a boundary thereof with the edge part and extend with a constant thickness equal to the second thickness toward the folding part.

15. The method of claim 14, wherein the folding part has the second thickness at a boundary thereof with the flat part, extends to the groove, and is decreased to a first thickness.

16. The method of claim 15, wherein the third thickness of the edge part is a thickness of the substrate, the third thickness is greater than the second thickness, and the second thickness is greater than the first thickness.

17. The method of claim 8, wherein the forming the groove in the folding part includes forming the groove concavely toward a lower surface of the substrate.

18. The method of claim 13, wherein the coating layer has a flat upper surface and covers the substrate.

19. The method of claim 8, wherein the coating layer includes a silicone-based resin.

20. An electronic device comprising:
a window in which a folding area, a first non-folding area adjacent to one side of the folding area, and a second non-folding area adjacent to an opposing side of the folding area are defined;
a display module disposed under the window; and
a processor which drives the display module,
wherein the window includes:
a substrate; and
a coating layer disposed on the substrate,
wherein the substrate includes:
a folding part overlapping the folding area and having a first thickness, wherein a groove is defined in the folding part;
a plurality of flat parts spaced apart from each other in a first direction with the folding part interposed therebetween and each having a second thickness; and
a plurality of edge parts spaced apart from each other in the first direction with the folding part and the flat parts interposed therebetween and each having a third thickness, and
wherein the third thickness is greater than the second thickness, and the second thickness is greater than the first thickness.
